(19) United States
(12) Patent Application Publication
(10) Pub. No.: US 2009/0101928 A1
(43) Pub. Date: Apr. 23, 2009

(54) LIGHT EMITTING DIODE AND METHOD OF FABRICATING THE SAME

(76) Inventors: Kyung Hyun Kim, Daejeon (KR); Rae Man Park, Daejeon (KR); Tae Youb Kim, Seoul (KR); Gun Yong Sung, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/577,728

(22) PCT Filed: Dec. 7, 2005
(86) PCT No.: PCT/KR05/04176

§ 371 Date: Apr. 23, 2007

(30) Foreign Application Priority Data
Dec. 8, 2004 (KR) 10-2004-0102927
Jun. 20, 2005 (KR) 10-2005-0052859

(51) Int. Cl. H01L 33/00; H01J 1/62; H01L 51/52; H01L 51/54; H01L 51/56; H01L 51/00

(52) U.S. Cl. 257/98; 313/504; 438/22; 438/99; 257/E33.064; 257/E51.019

(57) ABSTRACT

Provided are a light emitting diode and a method of fabricating the same. In an inorganic light emitting diode, at least one layer selected from a group consisting of an oxide layer, a nitride layer, and a metal layer is formed on an upper doping layer which is in contact with a transparent electrode, and the plasma treatment is performed on the resultant structure to form a plasma etching layer, thereby enhancing adhesion between the upper doping layer and the transparent electrode. In an organic light emitting diode, at least one layer selected from a group consisting of an oxide layer, a nitride layer, and a metal layer is formed on a plastic substrate which is in contact with a transparent electrode, and the plasma treatment is performed on the resultant structure to form a plasma etching layer, thereby enhancing adhesion between the substrate and the transparent electrode. As a result, the adhesion between the substrate and the transparent electrode or between the upper doping layer and the transparent electrode is enhanced and the layer separation from the transparent electrode is prevented, thereby improving efficiency of the light emitting diode and increasing the production yield.

### BACKGROUND ART

1. Field of the Invention

The present invention relates to a light emitting diode and a method of fabricating the same. More particularly, the present invention relates to a light emitting diode and a method of fabricating the same in which a layer being in contact with a transparent electrode of the light emitting diode is plasma treated to increase surface roughness, thereby enhancing adhesion.

2. Description of Related Art

In general, an inorganic light emitting diode includes an N-type or P-type lower doping layer, a light emitting layer, a P-type or N-type upper doping layer, and a transparent electrode which are sequentially stacked on an N-type or P-type semiconductor substrate. An organic light emitting diode includes a transparent electrode, an organic layer, and a metal electrode which are sequentially stacked on a substrate such as glass. In this case, indium tin oxide (ITO) or zinc oxide and aluminum (ZnO/Al) being a transparent electrode material, is deposited on a comparatively large area using a magnetron sputtering deposition method, a pulse laser deposition (PLD) method, or a chemical vapor deposition (CVD) method.

However, in the case where the above conventional deposition method is used in fabricating a micron-sized inorganic light-emitting diode, there occurs a phenomenon that the transparent electrode is separated from the upper doping layer during an etching process due to poor adhesion between the transparent electrode and the light emitting layer or the upper doping layer, thereby deteriorating the device characteristics and decreasing yield. In the meantime, in a flexible display mainly using a plastic substrate, when a transparent electrode layer is formed on the plastic substrate using a conventional deposition method, the substrate and the transparent electrode layer are separated from each other during an etching process due to poor adhesion, thereby deteriorating the device characteristics and decreasing yield.

Accordingly, the inventors of the present invention have researched a method for improving adhesion of a contact layer with the transparent electrode and increasing the contact force, and have discovered that, when an oxide layer, a nitride layer and a metal layer are formed and plasma-treated on a layer contacting with the transparent electrode and then the surface of the formed layer is etched to form the transparent electrode, the surface roughness increases and the adhesion is improved at the contact layer with the transparent electrode, thereby improving the device characteristics and the efficiency of the light emitting diode and concurrently increasing the production yield.

### SUMMARY OF THE INVENTION

The present invention is directed to implementation of an inorganic light emitting diode having a plasma etching layer on a transparent electrode layer.

The present invention is also directed to implementation of a method of fabricating an inorganic light emitting diode having a plasma etching layer on a transparent electrode layer.

The present invention is also directed to implementation of an organic light emitting diode having a plasma etching layer on a substrate including a transparent electrode layer.

The present invention is also directed to implementation of a method of fabricating an organic light emitting diode having a plasma etching layer on a substrate including a transparent electrode layer.

One aspect of the present invention is to provide an inorganic light emitting diode including: a substrate; a lower doping layer formed on the substrate; a light emitting layer formed on the lower doping layer; an upper doping layer formed on the light emitting layer; a plasma etching layer formed of at least one layer selected from the group consisting of an oxide layer, a nitride layer, and a metal layer on the upper doping layer; and a transparent electrode layer formed on the plasma etching layer.

Another aspect of the present invention is to provide a method of fabricating an inorganic light emitting diode, the method including the steps of: forming a lower doping layer on a substrate; forming a light emitting layer on the lower doping layer; forming an upper doping layer on the light emitting layer; forming at least one layer selected from a group consisting of an oxide layer, a nitride layer, and a metal layer on the upper doping layer; etching a surface of the resultant layer using plasma to form a plasma etching layer; and forming a transparent electrode on the plasma etching layer.

Yet another aspect of the present invention is to provide an organic light emitting diode including: a substrate; a plasma etching layer formed of at least one layer selected from the group consisting of an oxide layer, a nitride layer, and a metal layer on the substrate; a transparent electrode layer formed on the plasma etching layer; an organic layer formed on the transparent electrode layer; and a metal electrode layer formed on the organic layer.

Still another aspect of the present invention is to provide a method for fabricating an organic light emitting diode, the method including the steps of: forming at least one layer selected from a group of consisting of an oxide layer, a nitride layer, and a metal layer on a plastic substrate; etching a surface of the resultant layer using plasma to form a plasma etching layer; forming an organic layer on the plasma etching layer; and forming a metal electrode layer on the organic layer.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a cross-sectional view illustrating a schematic structure of an inorganic light emitting diode according to an exemplary embodiment of the present invention;

FIG. 2 is a cross-sectional view illustrating a schematic structure of an inorganic light emitting diode according to another exemplary embodiment of the present invention;

FIG. 3 is a cross-sectional view illustrating a schematic structure of an organic light emitting diode according to yet another exemplary embodiment of the present invention;

FIGS. 4A and 4B are scanning electron microscopy (SEM) images showing sections depending on plasma treatment in the organic light emitting diode of FIG. 3; and

FIGS. 5A and 5B are optical microscope photographs showing emission images depending on plasma treatment in the organic light emitting diode of FIG. 3.

### DETAILED DESCRIPTION OF THE PREFERRED EMBODIMENTS

The present invention will now be described more fully with reference to the accompanying drawings, in which exemplary embodiments of the invention are shown. This invention may, however, be embodied in different forms and should not be construed as limited to the exemplary embodiments set forth herein. Rather, these exemplary embodiments are provided so that this disclosure will be thorough and complete, and will fully convey the scope of the invention to those skilled in the art.

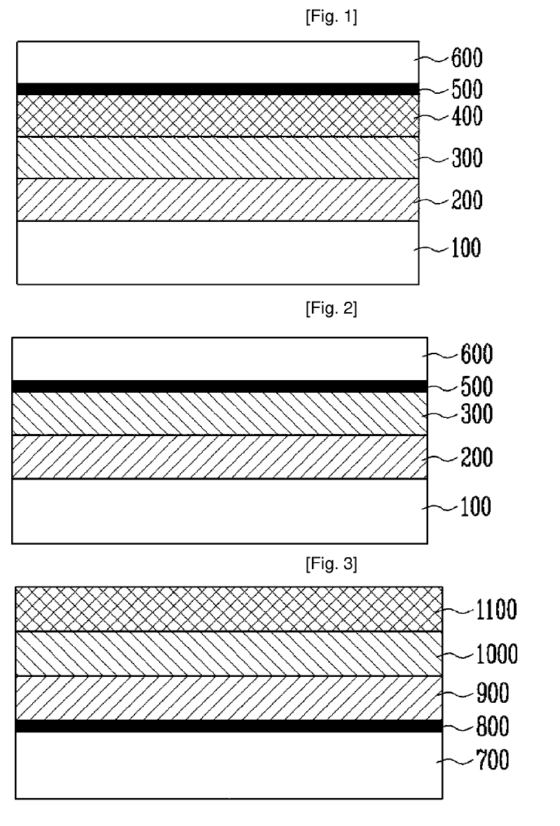

FIG. 1 is a cross-sectional view illustrating a schematic structure of an inorganic light emitting diode according to an exemplary embodiment of the present invention, and FIG. 2 is a cross-sectional view illustrating a schematic structure of an inorganic light emitting diode according to another exemplary embodiment of the present invention.

Referring to FIGS. 1 and 2, the inorganic light emitting diode according to the present invention has a sequentially stacked structure including a substrate 100, a lower doping layer 200, a light emitting layer 300, an upper doping layer 400, a plasma etching layer 500, and a transparent electrode 600, or a sequentially stacked structure including a substrate 100, a lower doping layer 200, a light emitting layer 300, a plasma etching layer 500, and a transparent electrode 600. In addition, an intermediate layer can be additionally stacked to improve efficiency of the light emitting diode.

The inorganic light emitting diode according to the present invention can be a silicon-based light emitting diode or a nitride-based light emitting diode.

The substrate 100 can be a P-type or N-type semiconductor substrate known in the art, and can be made of sapphire, GaN, SiC, ZnO, GaAs, or silicon (Si).

The lower doping layer 200 formed on the substrate 100 is a P-type or N-type doping layer, and may use a P-type or N-type compound and preferably, can employ GaAs:Be, GaAs:Si, GaN:Mg, SiC:N, SiC:P, SiC:B, ZnO:Ga, and ZnO:Al. The lower doping layer 200 can be formed to a suitable thickness using a method known in the art and preferably, is formed to a thickness of 50 to 500 nm using a magnetron sputtering deposition method, a pulse laser deposition (PLD) method, or a chemical vapor deposition (CVD) method.

The light emitting layer 300 formed in a predetermined region on the lower doping layer 200 is a P—N junction layer, and can employ one selected from a group of consisting of group III-V, group II-VI, and group IV-IV compound materials. The elements can be suitably selected depending on a light-emitting wavelength and can employ GaAs, GaAlAs, GaAsP, AlGalnP, AlAs, GaP, AlP, ZnSe, SiC, GaN, GaInN, and GaAlN, for example.

The light emitting layer 300 can be formed to a suitable thickness using a method known in the art and preferably, is formed to a thickness of 50 to 500 nm using the aforementioned deposition method.

The upper doping layer 400 can be formed to uniformly supply an external current onto the light emitting layer 300. When the lower doping layer 200 is a P-type doping layer, the upper doping layer 400 is an N-type doping layer, and when the lower doping layer 200 is an N-type doping layer, the upper doping layer 400 is a P-type doping layer. For example, the upper doping layer 400 can employ GaAs:Be, GaAs:Si, GaN:Mg, SiC:N, SiC:P, SiC:B, ZnO:Ga, and ZnO:Al.

The upper doping layer 400 can be formed to a suitable thickness using a method known in the art and preferably, is formed to a thickness of 50 to 500 nm using the aforementioned deposition method.

The plasma etching layer 500 is formed on the light emitting layer 300 or the upper doping layer 400 to enhance adhesion. In forming the plasma etching layer 500, an oxide layer, a nitride layer or a metal layer is formed to a thickness of less than 10 nm on the light emitting layer 300 or the upper doping layer 400, and then plasma treated and partially etched using a single or mixed gas of N₂, O₂, Ar, CF₄, SF₆ and NF₃, thereby increasing surface roughness. In order to prevent the formed oxide layer, nitride layer or metal layer from being damaged due to over-etching, the plasma treatment is performed using the selected gas at a pressure of 1×10⁻⁴ to 5×10⁻⁵ torr at a flow rate of 10 to 20 sccm for 5 to 10 seconds. Here a plasma power of less than 100 W is used.

In the meantime, in the case where the oxide layer or the nitride layer has been already formed on the light emitting layer 300 or the upper doping layer 400, the plasma treatment can be straightly performed without needing to form the oxide layer or the nitride layer. In the case where it is difficult to form the oxide layer or the nitride layer from the viewpoint of the characteristics of the device, the metal layer can be formed. After forming the metal layer, the plasma treatment or heat treatment can be also performed under the condition that the device characteristics are not deteriorated, thereby increasing the surface roughness.

The oxide layer can be formed of SiO₂, the nitride layer can be formed of Si₃N₄, and the metal layer can be formed of a single metal such as aurum (Au), argentum (Ag), aluminum (Al), nickel (Ni) or copper (Cu), or an alloy thereof.

The plasma-treatment layer has a thickness of less than 10 nm, preferably, 1 to 8 nm. Upon exceeding 10 nm, there occurs a problem in that the formed oxide layer, nitride layer, or metal layer is destroyed.

The transparent electrode 600 for a metal electrode is formed on the plasma etching layer 500. The transparent electrode 600 can be formed of indium tin oxide (ITO), InSnO, ZnO, SnO₂, NiO, or Cu₂SrO₂, or can be formed of N-type or P-type doped oxide such as CuInO₂:Ca and InO:Mo. It is desirable that the transparent electrode 600 has a thickness of 50 to 200 nm, and is formed using a method known in the art.

FIG. 3 is a cross-sectional view illustrating a schematic structure of an organic light emitting diode according to yet another exemplary embodiment of the present invention.

Referring to FIG. 3, the organic light emitting diode according to yet another exemplary embodiment of the present invention has a stacked structure of a substrate 700, a plasma etching layer 800, a transparent electrode layer 900, an organic layer 1000, and a metal electrode layer 1100. The organic layer 1000 includes a light emitting layer, and can include a hole injection layer and a hole transport layer between the transparent electrode layer and the light emitting layer. The organic layer 1000 can further include a hole blocking layer, an electron transport layer, and an electron injection layer between the light emitting layer and the metal electrode layer, and an intermediate layer for improving the inter-layer interface properties.

The substrate 700 can employ a substrate known in the art, and in particular, it is desirable to use a glass substrate or a transparent plastic substrate having excellent transparency, surface smoothness, ease of handling, and waterproofness. Further, the plastic substrate can use a substrate formed of a polymer compound selected from a group consisting of polyethylene terephthalate (PET), polyethersulfone (PES), polyimide (PI), and polycarbonate (PC).

The plasma etching layer 800 is formed on the substrate 700 to enhance adhesion. In forming the plasma etching layer 800, an oxide layer, a nitride layer or a metal layer is formed to a thickness of less than 10 nm on the substrate 700, and then plasma treated and partially etched using a single or mixed gas of N₂, O₂, Ar, CF₄, SF₆ and NF₃, thereby increasing surface roughness. The plasma treatment is performed using the selected gas at a pressure of 1×10⁻⁴ to 5×10⁻⁵ torr at a flow rate of 10 to 20 sccm for 5 to 10 seconds. Here a plasma power of less than 100 W is used.

In the meantime, in the case where the oxide layer or the nitride layer has been already formed on the substrate 700, the plasma treatment can be straightly performed without needing to form the oxide layer or the nitride layer. In the case where it is difficult to form the oxide layer or the nitride layer from the viewpoint of the characteristics of the device, the metal layer can be formed. After forming the metal layer, the plasma treatment or heat treatment can be also performed under the condition that the device characteristics are not deteriorated, thereby increasing the surface roughness.

The oxide layer can be formed of SiO₂, and the nitride layer can formed of Si₃N₄, and the metal layer can formed of a single metal of aurum (Au), argentums (Ag), aluminum (Al), nickel (Ni) or copper (Cu), or an alloy thereof.

The plasma-treatment layer has a thickness of less than 10 nm, preferably, 1 to 8 nm. Upon exceeding 10 nm, there occurs a problem in that the formed oxide layer, nitride layer, or metal layer is damaged.

The transparent electrode layer 900 is formed on the plasma etching layer 500 using a method known in the art. The transparent electrode 600 can be formed of ITO, InSnO, ZnO, SnO₂, NiO, or Cu₂SrO₂, or formed of N-type or P-type doped oxide such as CuInO₂:Ca and InO:Mo. It is desirable that the transparent electrode layer 900 has a thickness of 50 to 200 nm, and is formed using a method known in the art.

Consequently, the organic layer 1000 is formed on the transparent electrode layer 900. The organic layer 1000 can include a hole injection layer, a hole transport layer, a light emitting layer, a hole blocking layer, an electron transport layer, and an electron injection layer.

The hole injection layer can be formed of copper phthalocyanine (CuPc) or starburst amine based compounds, that is, 4,4′,4″-Tri(N-carbazolyl)triphenylamine (TCTA), 4,4′,4″-Tris(3-methylphenyl-phenylamino)triphenylamine (m-MTDATA), and IDE406 (Idemitsu material). The hole transport layer can be formed of N,N-bis(3-methylphenyl)-N,N-diphenyl-[1,1-biphenyl]-4,4-diamine (TPD), N,N-di(naphthalene-1-yl)-N,N-diphenyl-benzidene (α-NPD), and IDE320 (Idemitsu material).

The light emitting layer uses a material known in the art, and is not particularly limited and uses an aluminum complex (eg. Alq3 (tris(8-quinolinolato)-aluminum), BAlq, SAlq, Almq3, a gallium complex (eg. Gaq′2OPiv, Gaq′2OAc, 2(Gaq′2)), a fluorine-based polymer, polyparaphenyline vinylene or a derivative thereof, a biphenyl derivative, a spiro polyfluorene-based polymer, and so on.

The hole blocking layer can be formed of BAlq, BCP, and TPBI having electron transportability and having a greater ionization potential than a light emitting compound.

Further, the electron transport layer can be formed of an electron transport material such as Alq3.

Electron injection material forming the electron injection layer is not particularly limited, but can use LiF, NaCl, CsF, Li₂O, BaO, and Li.

In the organic layer 1000, the hole injection layer, the hole transport layer, the light emitting layer, the hole blocking layer, the electron transport layer or the electron injection layer can be formed to a thickness known in the art, using a method such as a vacuum deposition or spin coating method.

The metal electrode layer 1100 can be formed of lithium (Li), magnesium (Mg), aluminum (Al), aluminum-lithium (Al—Li), calcium (Ca), magnesium-indium (Mg—In), and magnesium-argentums (Mg—Ag), on the organic layer 1000. It is desirable that the formed metal electrode layer 1100 has a thickness of 200 to 300 nm.

Hereinafter, the present invention will be in more detail described below, but is not limited to an embodiment.

### Embodiment 1

Fabrication of Inorganic Light Emitting Diode

A P-type doping layer was formed using SiC:B, on a silicon (Si) substrate under a vacuum of 500 mTorr to a thickness of 200 nm. Subsequently, a light emitting layer was formed using SiH₄, on the P-type doping layer under the vacuum of 500 mTorr. An N-type doping layer was formed using SiC:P, on the light emitting layer under a vacuum of 500 mTorr to a thickness of 200 nm.

An oxide layer was grown using SiH4 and O2, on the N-type doping layer under a vacuum of 500 mTorr to a thickness of 7 nm. Subsequently, the resultant structure was dry etched for ten seconds, using argon (Ar) gas, at a flow rate of 20 sccm at a pressure of 4.6×10⁻⁴torr with a plasma power of 100 W and a bias voltage of 230 V maintained. Subsequently, ITO was formed under a vacuum of 15 mTorr to a thickness of 100 nm, thereby fabricating an inorganic light emitting diode.

### Second Embodiment

Fabrication of Organic Light Emitting Diode

An oxide layer was grown to a thickness of 7 nm on a polyethersulfone (PES) substrate under a vacuum of 10 mTorr using a magnetron sputtering method. Subsequently, the resultant structure was treated and etched at its surface for ten seconds, using argon (Ar) gas, at a flow rate of 20 sccm at a pressure of 4.6×10⁻⁴ torr with a plasma power of 100 W and a bias voltage of 230 V maintained. Subsequently, ITO was formed to a thickness of 180 nm under a vacuum of 15 mTorr, thereby forming a transparent electrode layer. Subsequently, triphenylamine dimmer (NPD) was thermally deposited to a thickness of 50 nm under vacuum to form an NPD layer on the transparent electrode layer, and Alq3 was deposited to form an Alq3 layer with a thickness of 50 nm on the NPD layer, thereby forming an organic layer.

Aluminum (Al) was thermally deposited under vacuum to form a metal electrode with a thickness of 150 nm on the organic layer, thereby fabricating an organic light emitting diode.

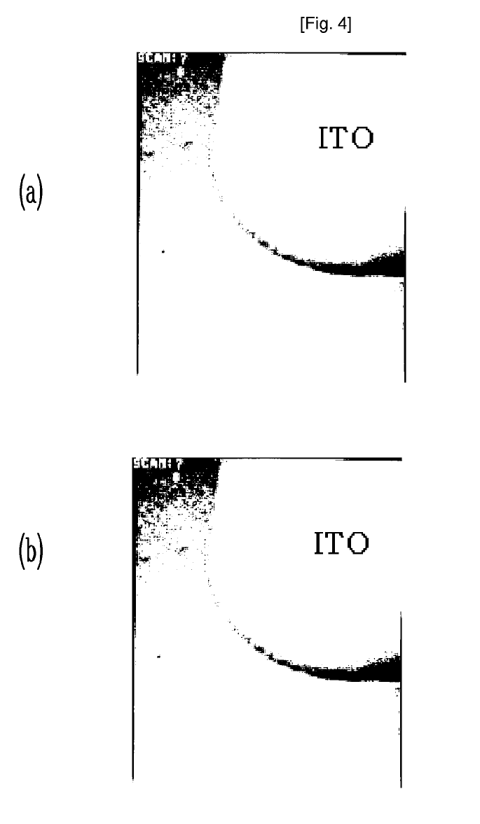

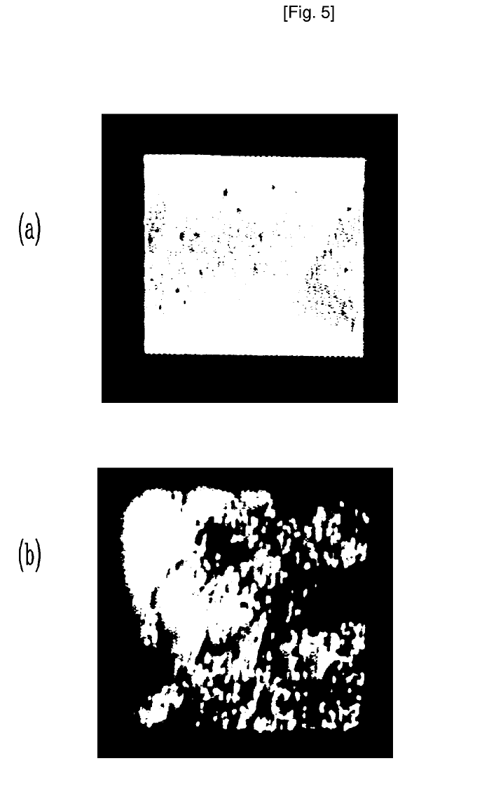

FIGS. 4A and 4B are scanning electron microscopy (SEM) images showing a section (a) of the light emitting diode where the plasma treatment is performed using argon (Ar) gas, and then the ITO is deposited on the polyethersulfone substrate, and a section (b) of the light emitting diode where the ITO is deposited on the polyethersulfone substrate without the plasma treatment. Further, emission images of the light emitting diodes are shown in FIGS. 5A and 5B, respectively.

As shown in FIG. 4A, it could be appreciated that the substrate was not separated from the ITO layer in the case where the plasma treatment was performed. Accordingly, as shown in FIG. 5A, it could be appreciated that an entire light emitting surface was very uniform in emission properties. On the contrary, as shown in FIG. 4B, it could be appreciated that the substrate was slightly separated from the ITO layer in the case where the plasma treatment was not performed. Accordingly, as shown in FIG. 5B, the local emission properties were shown.

As described above, in the inorganic light emitting diode according to the present invention, the oxide layer, the nitride layer or the metal layer is formed and plasma-treated on the upper doping layer or the light emitting layer contacting with the transparent electrode to increase the surface roughness, and then the transparent electrode is formed to enhance adhesion and prevent layer separation from the transparent electrode, thereby improving the performance of the inorganic light emitting diode.

Further, in the organic light emitting diode according to the present invention, the oxide layer, the nitride layer, or the metal layer is formed and plasma treated on the substrate contacting with the transparent electrode, in particular, on the plastic substrate to increase the surface roughness, and then the transparent electrode is formed to prevent the separation of the substrate and the transparent electrode, thereby improving efficiency of the light emitting diode.

Furthermore, in the light emitting diode according to the present invention, the interlayer adhesion can be improved and the layer separation occurring during the manufacturing process can be prevented, thereby improving production yield.

While the invention has been shown and described with reference to certain exemplary embodiments thereof, it will be understood by those skilled in the art that various changes in form and details may be made therein without departing from the spirit and scope of the invention as defined by the appended claims.

1. In inorganic light emitting diode comprising:
a substrate;
a lower doping layer formed on the substrate;
a light emitting layer formed on the lower doping layer;
an upper doping layer formed on the light emitting layer;
a plasma etching layer formed of at least one layer selected from a group consisting of an oxide layer, a nitride layer, and a metal layer on the upper doping layer; and
a transparent electrode layer formed on the plasma etching layer.

2. The inorganic light emitting diode according to claim 1, wherein the upper doping layer is excluded.

3. The inorganic light emitting diode according to claim 1, wherein the substrate is a P-type or N-type semiconductor substrate, the lower doping layer is a P-type or N-type doping layer, and the upper doping layer is an N-type or P-type doping layer.

4. The inorganic light emitting diode according to claim 1, wherein the plasma etching layer has a thickness of less than 10 nm.

5. The inorganic light emitting diode according to claim 1, wherein the oxide layer is formed of SiO₂, the nitride layer is formed of Si₃N₄, and the metal layer is formed of at least one metal selected from a group consisting of aurum (Au), argentum (Ag), aluminum (Al), nickel (Ni), and copper (Cu).

6. The inorganic light emitting diode according to claim 1, wherein the transparent electrode is formed of at least one compound selected from a group consisting of ITO, InSnO, ZnO, SnO₂, NiO, and Cu₂SrO₂, or formed of CuInO₂:Ca or InO:Mo obtained by doping N-type or P-type dopants into oxide.

7. A method of fabricating an inorganic light emitting diode, the method comprising the steps of:
forming a lower doping layer on a substrate;
forming a light emitting layer on the lower doping layer;
forming an upper doping layer on the light emitting layer;
forming at least one layer selected from a group consisting of an oxide layer, a nitride layer, and a metal layer on the upper doping layer;
etching a surface of the resultant layer using plasma to form a plasma etching layer; and
forming a transparent electrode on the plasma etching layer.

8. The method according to claim 7, wherein the plasma treatment is performed for five to ten seconds at a flow rate of 10 to 20 sccm under a pressure of 1×10⁻⁴ to 5×10⁻⁵ torr, using at least one gas selected from a group consisting of N₂, O₂, Ar, CF₄, SF₆, and NF₃.

9. An organic light emitting diode comprising:
a substrate;
a plasma etching layer formed of at least one layer selected from a group consisting of an oxide layer, a nitride layer, and a metal layer on the substrate;
a transparent electrode layer formed on the plasma etching layer;
an organic layer formed on the transparent electrode layer; and
a metal electrode layer formed on the organic layer.

10. The organic light emitting diode according to claim 9, wherein the substrate is a plastic substrate, and the organic layer is a light emitting layer.

11. The organic light emitting diode according to claim 9, wherein the plasma etching layer has a thickness of less than 10 nm.

12. The organic light emitting diode according to claim 9, wherein the oxide layer is formed of SiO₂, the nitride layer is formed of Si₃N₄, and the metal layer is formed of at least one metal selected from a group consisting of aurum (Au), argentum (Ag), aluminum (Al), nickel (Ni), and copper (Cu).

13. The organic light emitting diode according to claim 9, wherein the transparent electrode is formed of at least one compound selected from a group consisting of ITO, InSnO, ZnO, SnO₂, NiO, and Cu₂SrO₂, or formed of CuInO₂:Ca or InO:Mo obtained by doping N-type or P-type dopants into oxide.

14. A method of fabricating an organic light emitting diode, the method comprising the steps of:
forming at least one layer selected from a group of consisting of an oxide layer, a nitride layer, and a metal layer on a plastic substrate;
etching a surface of the resultant layer using plasma to form a plasma etching layer;
forming an organic layer on the plasma etching layer; and
forming a metal electrode layer on the organic layer.

15. The method according to claim 14, wherein the plasma treatment is performed for five to ten seconds at a flow rate of 10 to 20 sccm under a pressure of 1×10⁻⁴ to 5×10⁻⁵ torr, using at least one gas selected from a group consisting of N₂, O₂, Ar, CF₄, SF₆, and NF₃.
